(19) United States
(12) Patent Application Publication
(10) Pub. No.: US 2012/0295432 A1
(43) Pub. Date: Nov. 22, 2012

(54) METHOD OF FORMING SEMICONDUCTOR DEVICE

(75) Inventors: Joo Kyoung SONG, Seoul (KR); Hyoung Soon Yune, Seoul (KR)

(73) Assignee: Hynix Semiconductor Inc., Icheon (KR)

(21) Appl. No.: 13/368,268

(22) Filed: Feb. 7, 2012

(30) Foreign Application Priority Data
May 17, 2011 (KR) 10-2011-0046531

(51) Int. Cl. H01L 21/28

(52) U.S. Cl. 438/585; 257/E21.19

(57) ABSTRACT

A method of forming a semiconductor device includes forming an interlayer insulating layer over the semiconductor substrate of a cell region, and forming gate structures over the semiconductor substrate of a peripheral region. Reserved bit line regions are formed in the cell region by etching the interlayer insulating layer, and gates are formed by etching the gate structures in the peripheral region. A capping insulating layer and an isolation layer are formed over the reserved bit line regions and the gates, the isolation layer of the cell region is removed, and an etch-back process is performed on the capping insulating layer, and bit lines are formed in the respective reserved bit line regions. Semiconductor device yields can be enhanced because patterns having a fine critical dimension can be formed in peripheral regions with an increased degree of integration.

### CROSS-REFERENCE TO RELATED APPLICATION

Priority to Korean patent application number 10-2011-0046531, filed on May 17, 2011, which is incorporated by reference in its entirety, is claimed.

### BACKGROUND OF THE INVENTION

Embodiments of the present invention relate to a semiconductor device and a method of forming the same. Many electronic appliances are equipped with semiconductor devices. A semiconductor device includes electronic elements, such as a transistor, a resistor, and a capacitor. The electronic elements are designed to perform specific functions of the electronic appliance and then are integrated on a semiconductor substrate. For example, an electronic appliance, such as a computer or a digital camera, includes a memory chip for storing information and a processing chip for information control. The memory chip and the processing chip include the electronic elements integrated on the semiconductor substrate.

Meanwhile, the degree of integration of semiconductor devices is increasing as technology evolves. As the degree of integration increases, the dimensions of semiconductors are decreased, leading to finer detail in patterns disposed on the semiconductors. As the patterns of the semiconductor devices become fine and the degree of integration of the semiconductor devices is increased, the chip area is generally increased in proportion to an increase of the memory capacity, but the area of a cell region where the patterns of the semiconductor device are formed is decreased. Accordingly, fine patterns having reduced critical dimensions (CD) need to be formed because a larger number of patterns must be formed within a limited cell region in order to secure a desired memory capacity.

To facilitate a reduction of the area per cell, design rules of smaller nano-scale critical dimensions (CD) having a several nm level to a several tens of nm level are applied. To this end, there is a need for new technology for forming finer patterns, such as fine contact hole patterns each having a nano-scale opening size or fine line patterns each having a nano-scale width. An ability to reduce the size of a structure, such as a gate in a field effect transistor (FET), is performed by photolithography technology.

A photolithography process is based on a principle that the properties of specific chemicals (e.g., photoresist) are changed by a chemical reaction when the chemicals are exposed to light. Photolithography is a process of forming the same patterns as mask patterns by selectively radiating light to the photoresist using a mask having desired patterns. The photolithography process includes a coating process of coating a photoresist film, an exposure process of selectively radiating light using a mask, and a development process of forming patterns so that parts exposed to light are removed or maintained by using a developer. The photoresist may be a positive photoresist or a negative photoresist, and may be a silicon-containing dry-developed resist. In case of the positive photoresist, a photochemical reaction is generated using light.

The photolithography process depends on a wavelength of light. A current photolithography process is performed using exposure equipment employing short wavelength light sources, such as KrF and ArF. However, the resolution of patterns obtained from the short wavelength light sources is about 0.1 μm. Thus, current photolithography processes have a limit to the fabrication of high-integrated semiconductor devices including patterns with features smaller than the resolution of 0.1 μm.

For example, current photolithography processes have a limited ability to fabricate a feature having a critical dimension (CD) reduced by aberration and focus and proximity effects in the use of a light source.

FIG. 1 shows the gates of a peripheral region in the known art, wherein FIG. 1(i) is a design layout diagram, FIG. 1(ii) is a layout diagram in which an optical proximity effect has been corrected, and FIG. 1(iii) is a diagram showing photoresist patterns after development.

As shown in FIG. 1, if gates are formed in a peripheral region according to the known art, a design layout, such as that of FIG. 1(i), is difficult to implement owing to the influence of an optical proximity effect. For this reason, the layout shown in FIG. 1(ii) with a corrected optical proximity effect is designed by inserting auxiliary patterns for compensating for the optical proximity effect into the periphery of the design layout.

The photoresist patterns shown in FIG. 1(iii) are formed by using the layout of FIG. 1(ii), which has the optical proximity effect corrected, as a mask through exposure and development processes. However, there are limits to the amount of correction that can be accomplished. Although a feature is designed to have a shape with right angled corners as shown in FIG. 1(i), the inability of a photolithography process to resolve such fine details results in features with rounded edges as shown in FIG. 1(iii). Consequently, variation is present between features that are designed to be uniform. For example, the spacing between adjacent features may vary. In other words, there is a problem in that it is difficult to resolve features to have the same shapes as those of an original layout even when an optical proximity effect is corrected.

### BRIEF SUMMARY OF THE INVENTION

A method of forming a semiconductor device of the present invention includes forming an interlayer insulating layer over the semiconductor substrate of a cell region and forming gate structures over the semiconductor substrate of a peripheral region, forming reserved bit line regions in the cell region by etching the interlayer insulating layer and forming gates by etching the gate structures in the peripheral region, forming a capping insulating layer and an isolation layer over the reserved bit line regions and the gates, removing the isolation layer of the cell region and performing an etch-back process on the capping insulating layer, and forming bit lines in the respective reserved bit line regions.

The method further includes forming gate electrodes buried in the cell region, before forming the interlayer insulating layer.

Each of the gate structures is a line pattern comprises including contact hole patterns.

The gate structure includes a line and space pattern.

A forming-reserved-bit-line-regions-in-the-cell-region-by-etching-the-interlayer-insulating-layer includes forming first mask patterns over the interlayer insulating layer of the cell region and etching the interlayer insulating layer by using the first mask patterns as an etch mask.

A forming-gates-by-etching-the-gate-structures-in-the-peripheral-region includes forming the first mask patterns and simultaneously forming second mask patterns over the gate structures and etching the gate structures by using the second mask patterns as an etch mask.

If the gate structure is the line pattern including the contact hole patterns, the second mask patterns include line and space patterns which are vertical to the line patterns and overlapped with the contact hole patterns.

If the gate structure includes the line and space pattern, the second mask pattern includes a hole pattern, a first space pattern overlapped with a central portion of the hole pattern, and a second space pattern spaced apart from the first space pattern.

The long-axis direction of the line and space pattern is vertical to the long-axis direction of the first space pattern.

Each of the gates has a ‘[’ form.

### BRIEF DESCRIPTION OF THE DRAWINGS

FIG. 1 shows the gates of a peripheral region in the known art, wherein FIG. 1(i) is a design layout diagram, FIG. 1(ii) is a layout diagram in which an optical proximity effect has been corrected, and FIG. 1(iii) is a diagram showing photoresist patterns after development;

FIG. 2 is a plan view of a semiconductor device in a cell region according to the present invention;

FIGS. 3A and 3B are diagrams showing a method of forming a semiconductor device according to an embodiment of the present invention, wherein FIG. 3_(i) is a cross-sectional view taken along line Y-Y′ of FIG. 2, FIG. 3_(ii) is a cross-sectional view taken along line X-X′ of FIG. 2, FIG. 3_(iii) is a plan view of a peripheral region, and FIG. 3_(iv) is a cross-sectional view taken along line X₁-X₁′ of FIG. 3_(iii);

FIGS. 3C to 3G are diagrams showing the method of forming a semiconductor device according to an embodiment of the present invention, wherein FIG. 3_(i) is a cross-sectional view taken along line Y-Y′ of FIG. 2, FIG. 3_(ii) is a cross-sectional view taken along line X-X′ of FIG. 2, and FIG. 3_(iii) is a cross-sectional view taken along line X₁-X₁′ of FIGS. 3A and 3B;

FIGS. 4A to 4C are perspective views showing a method of forming a semiconductor device in a peripheral region according to an embodiment of the present invention;

FIGS. 5 and 6 are plan views of the semiconductor device in the peripheral region according to an embodiment of the present invention; and

FIGS. 7A to 7C are plan views of a method of forming a semiconductor device according to another embodiment of the present invention.

### DESCRIPTION OF EMBODIMENTS

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

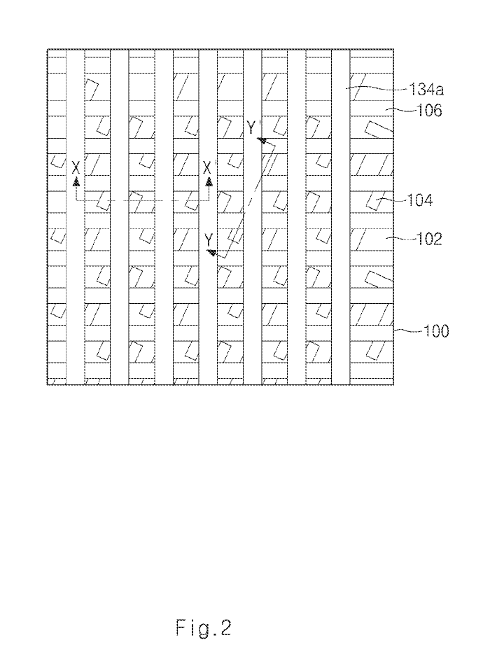

FIG. 2 is a plan view of a semiconductor device in a cell region according to the present invention. As shown in FIG. 2, the semiconductor device includes active regions 104 extended in oblique lines and spaced apart from one another, gates 106 formed to cross the active regions 104, and bit lines 134a formed above the gates 106.

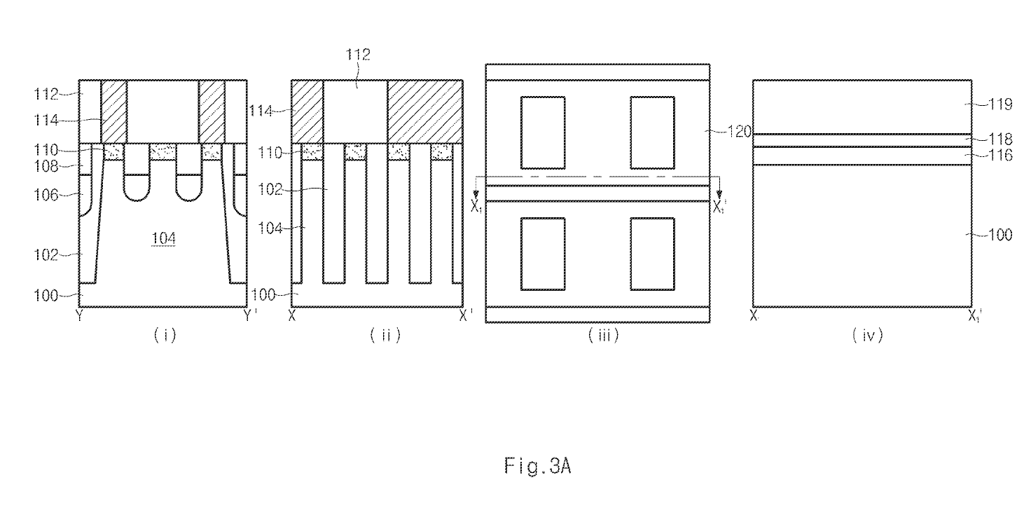

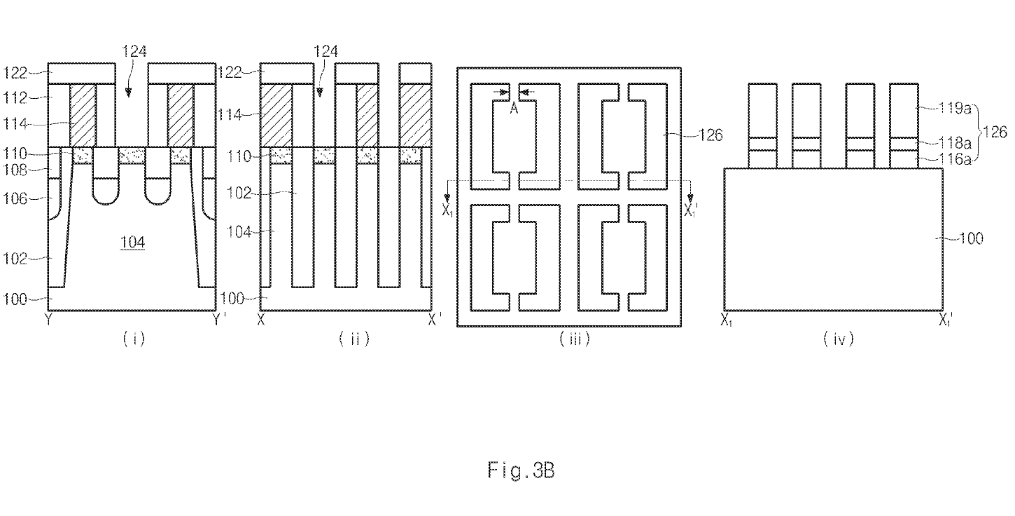

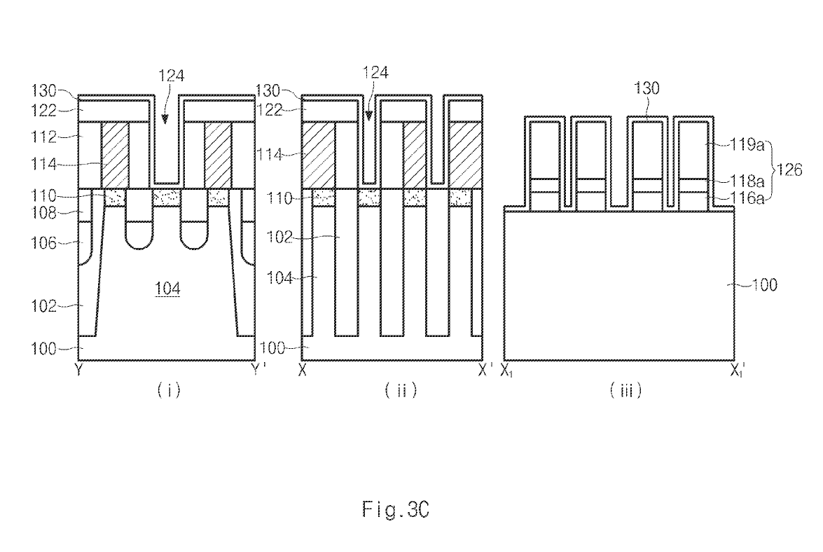

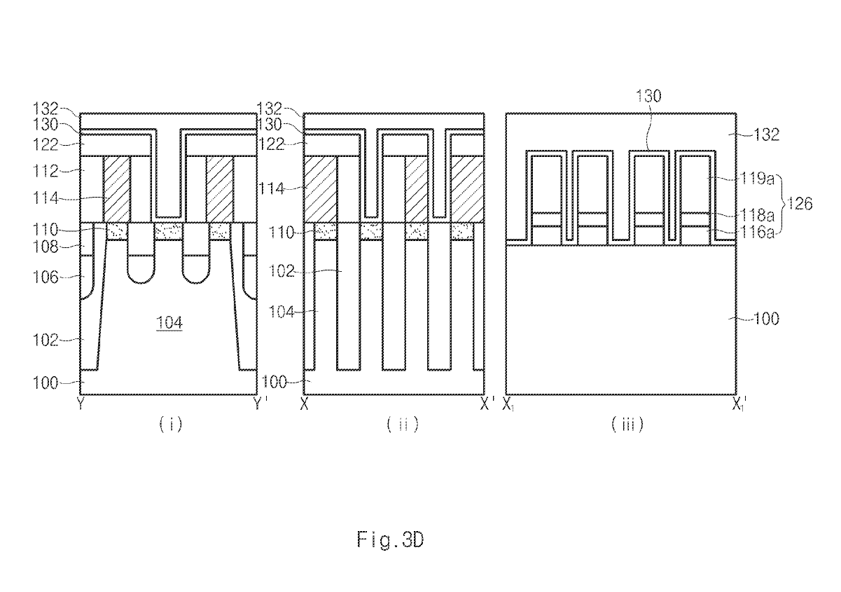

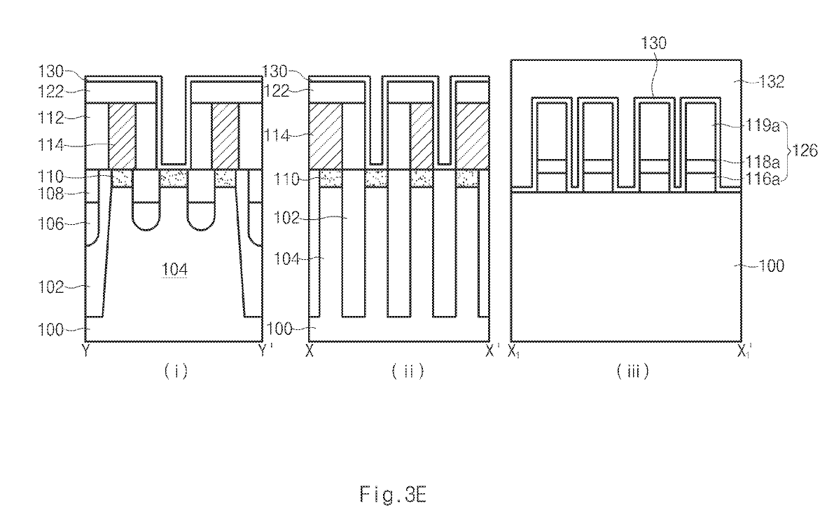

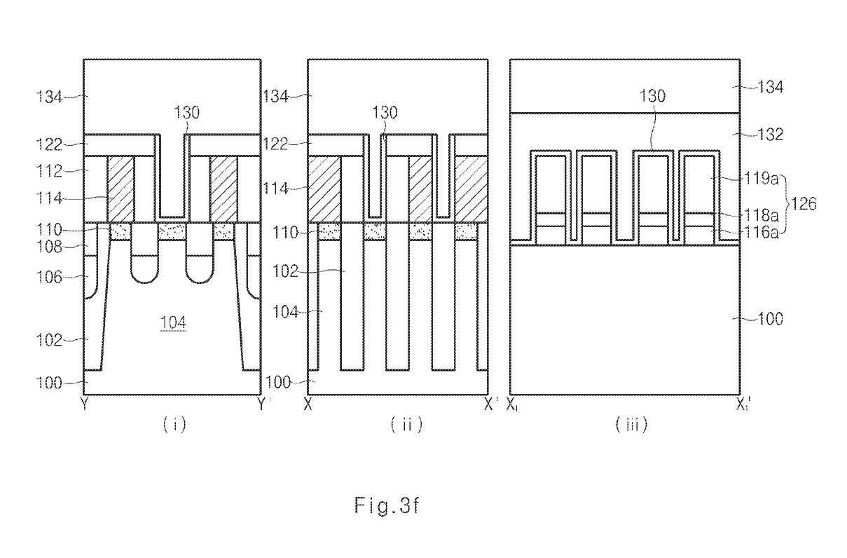

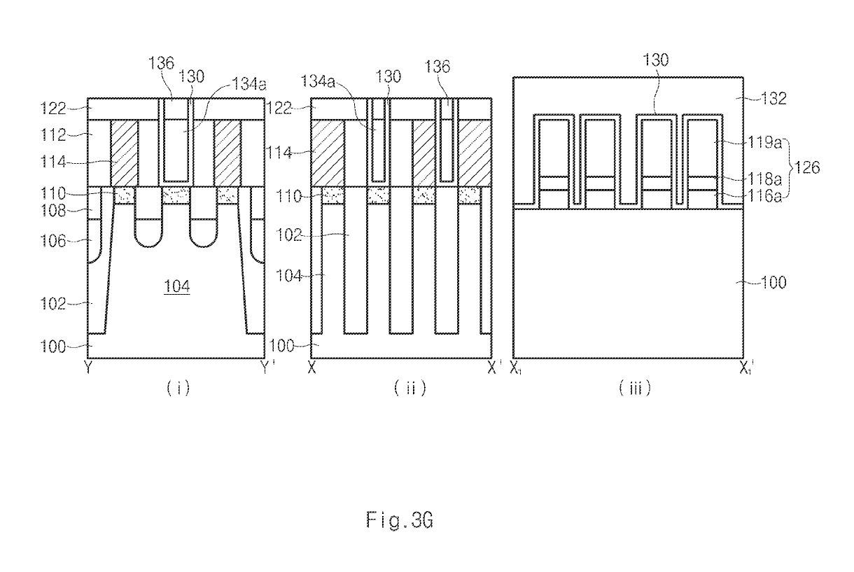

FIGS. 3A and 3B are diagrams showing a method of forming a semiconductor device according to the present invention, wherein FIG. 3_(i) is a cross-sectional view taken along line Y-Y′ of FIG. 2, FIG. 3_(ii) is a cross-sectional view taken along line X-X′ of FIG. 2, FIG. 3_(iii) is a plan view of a peripheral region, and FIG. 3_(iv) is a cross-sectional view taken along line X₁-X₁′ of FIG. 3_(iii). Furthermore, FIGS. 3C to 3G are diagrams showing a method of forming a semiconductor device according to the present invention, wherein FIG. 3_(i) is a cross-sectional view taken along line Y-Y′ of FIG. 2, FIG. 3_(ii) is a cross-sectional view taken along line X-X′ of FIG. 2, and FIG. 3_(iii) is a cross-sectional view taken along line X₁-X₁′ of FIGS. 3A and 3B.

As shown in FIGS. 3A(i) and (ii), gate electrodes 106 are buried in a semiconductor substrate 100 including the active regions 104 defined by isolation layers 102. An insulating layer 108 is formed over each of the gate electrodes 106. Next, an ion implantation region 110 is formed on a surface of each of the active regions 104. After an interlayer insulating layer 112 is formed over the semiconductor substrate 100, storage electrode contact plugs 114 coupled to the respective ion implantation regions 110 are formed to penetrate the interlayer insulating layer 112.

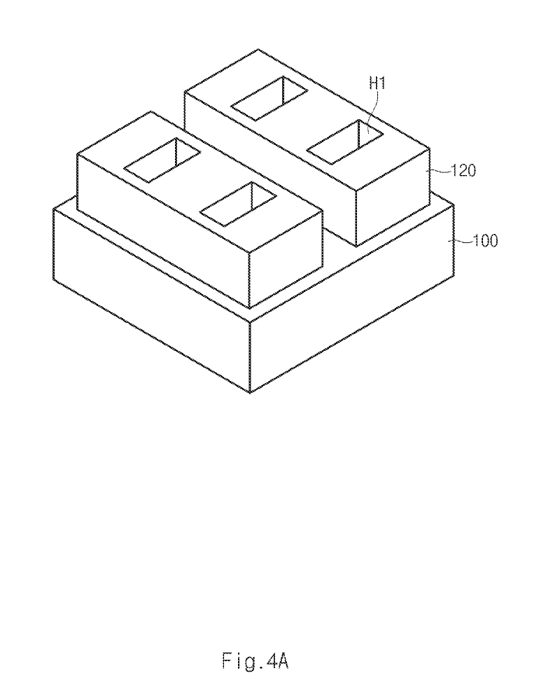

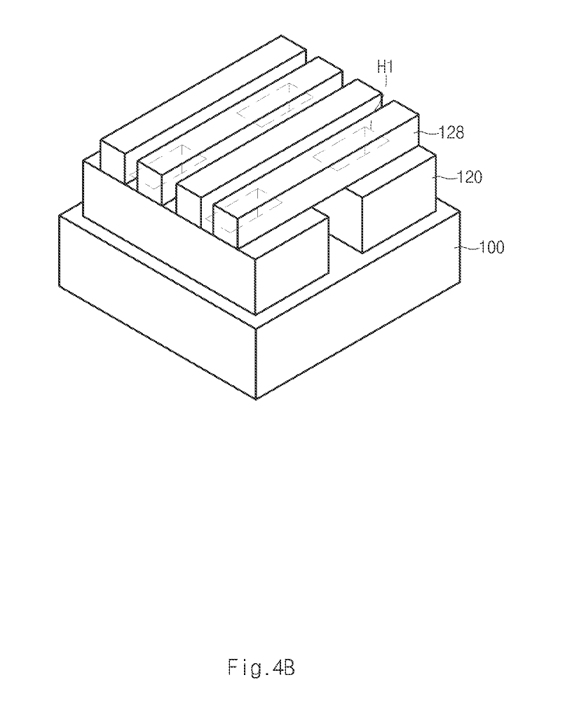

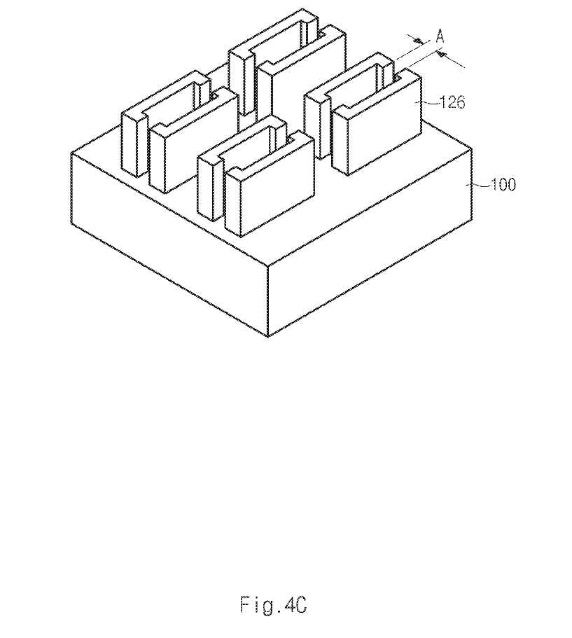

As shown in FIGS. 3A(iii) and (iv), first patterns 120 are formed in the peripheral region of the semiconductor substrate 100. The first pattern 120 includes a gate structure in which a gate oxide layer 116, a gate electrode 118, and a hard mask layer 119 are stacked. For reference, it is preferred that the first pattern 120 in the peripheral region has a shape, such as that shown in FIG. 4A.

As shown in FIGS. 3B(i) and (ii), in order to open the ion implantation region 110 in a central portion of the active region 104, first mask patterns 122 are formed on the interlayer insulating layers 112, and the interlayer insulating layer 112 is etched by using the first mask patterns 122 as an etch mask, thereby forming reserved bit line regions 124. At the same time, as shown in FIGS. 3B(iii) and (iv), gates 126, each having a structure of a gate oxide layer pattern 116a, a gate electrode pattern 116a, and a hard mask pattern 119a, are formed by etching the hard mask layer 119, the gate electrode 118, and the gate oxide layer 116. That is, the reserved bit line regions 124 of the cell region and the gates 126 of the peripheral region are formed at the same time.

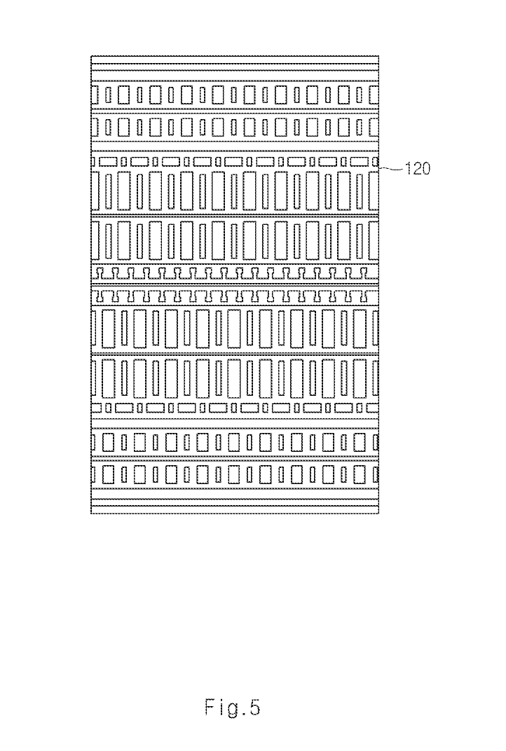

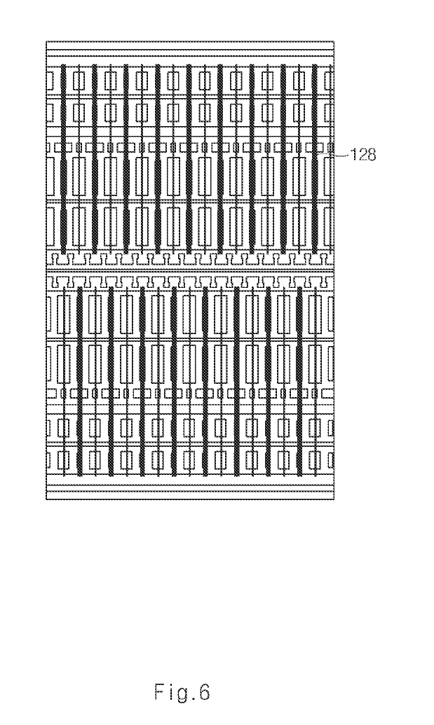

For reference, a method of forming the gates 126 is described in more detail with respect to FIGS. 4A to 4C. FIGS. 4A to 4C are perspective views showing a method of forming a semiconductor device in a peripheral region. FIGS. 5 and 6 are plan views of embodiments of a semiconductor is device in the peripheral region.

In the embodiment shown in FIG. 4A, the first patterns 120 are formed in the peripheral region. Each of the first patterns 120 may be a line pattern including hole patterns H1, and that the first pattern 120 may have a shape such as that shown in FIG. 5.

As shown in FIG. 4B, second mask patterns 128 of a line and space type are formed in a direction perpendicular to the long-axis direction of the first patterns 120. In an embodiment, the lines of the second mask patterns 128 that overlap holes, such as hole H1 of FIG. 4A, have a smaller linewidth than lines disposed between holes, so that every other line has a first width and every other line has a second width wider than the first width. In FIG. 6, the second mask patterns 128 comprising lines with alternating line widths are shown by darker lines on a layout for an area larger than that shown in FIG. 4B. In an embodiment, the second mask patterns 128 be formed simultaneously with the first mask patterns 122 of FIGS. 3B (i) and (ii).

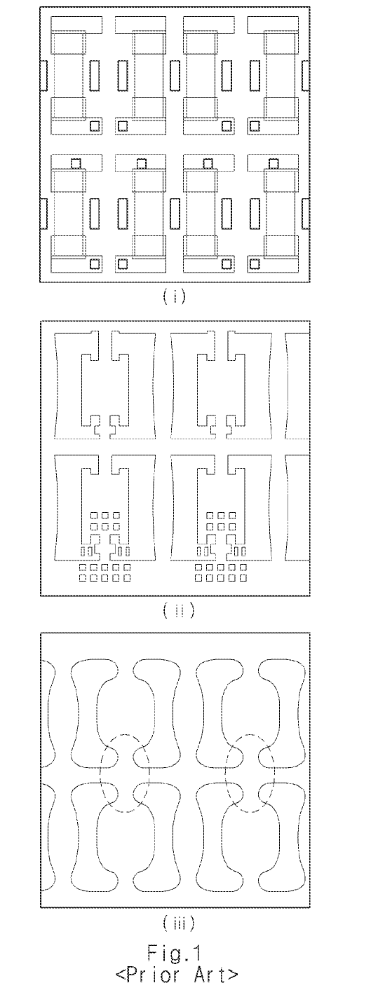

As shown in FIG. 4C, the first patterns 120 may be etched by using the second mask patterns 128 as an etch mask, thereby forming square bracket shaped gates 126. Consequently, the adjacent gates 126 are spaced from each other by interval A. Gates 126 may be formed by a process with a plurality of steps such as the process shown in FIGS. 4A to 4C, as opposed to a process using a single etching step as shown in FIG. 1. In an embodiment, the method for forming gates illustrated by FIG. 4A to 4C is performed simultaneously with a process of forming reserved bit line is regions in a cell region, so that costs and time associated with the method are not significantly increased. In an embodiment, the cost and time for implementing a method according to FIG. 4A to 4C are lower than the cost and time for implementing a method according to FIG. 1.

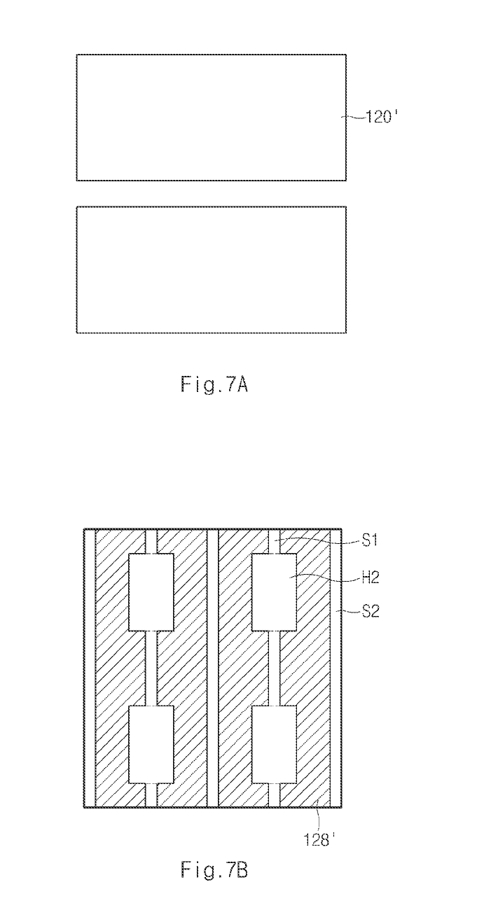

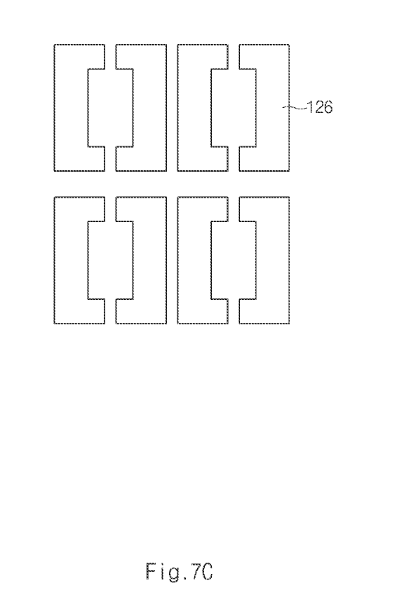

In another embodiment, a method such as the method illustrated by FIG. 7A to 7C can be used in place of the method according to FIG. 4A to 4C. FIGS. 7A to 7C are plan views of a method of forming a semiconductor device according to another embodiment of the present invention.

As shown in FIG. 7A, second patterns 120′ are formed in a peripheral region. In an embodiment, the second patterns 120′ include line patterns.

As shown in FIG. 7B, second mask patterns 128′ include a hole pattern H2, a first space pattern S1 formed to overlap with a central portion of the hole pattern H2, and a second space pattern S2 spaced apart from the first space pattern S1. Second mask patterns 128′ are formed on each of the second patterns 120′ shown by FIG. 7A. The long axis of the second mask patterns 128′ may be perpendicular to the long axis of the second patterns 120′.

As shown in FIG. 7C, the second patterns 120′ are etched by using the second mask patterns 128′ as an etch mask, thereby forming gates 126. Furthermore, costs and time necessary for additional processes can be reduced because the process of forming the gates 126 can be is performed simultaneously with a process of forming reserved bit line regions. The second mask patterns 128′ may be formed simultaneously with the first mask patterns 122 of FIGS. 3B (i) and (ii).

Methods of forming gates 126 with a I′ shape in the peripheral region have been described above. Subsequent processes are described below. FIGS. 3C to 3G are diagrams showing a method of forming a semiconductor device according to an embodiment of the present invention. For FIG. 3C to 3G, FIG. 3_(i) is a cross-sectional view taken along line Y-Y′ of FIG. 2, FIG. 3_(ii) is a cross-sectional view taken along line X-X′ of FIG. 2, and FIG. 3_(iii) is a cross-sectional view taken along line X-X′ of FIGS. 3A(iii) and 3B(iii).

As shown in FIG. 3C, a capping insulating layer 130 is formed on the reserved bit line regions 124 and the gates 126. The capping insulating layer 130 may be a nitride layer or an oxide layer.

As shown in FIG. 3D, an isolation layer 132 is formed on the capping insulating layer 130. The isolation layer 132 electrically isolates bit lines 134a (formed in a subsequent process) from the gates 126 in the peripheral region. The isolation layer 132 be a nitride layer or an oxide layer.

As shown in FIG. 3E, a mask (not shown) for opening the cell region shown in FIG. 3E(i) and 3E(ii) is formed in the peripheral region show in FIG. 3E(iii). Portions of the isolation layer 132 disposed over the cell region are removed by using the mask (not shown) as an etch mask. Subsequently, portions of capping insulating layer 130 disposed over first mask patterns 122 are removed, while portions of capping insulating layer 130 disposed over ion implantation regions 110 are left intact (for example by performing an etch-back process).

As shown in FIG. 3F, a conductive layer 134 is formed on upper surfaces disposed over the ion implantation regions 110 and the mask patterns 122. In an embodiment, the conductive layer 134 may include tungsten (W) and be configured to subsequently form bit lines. The conductive layer 134 is electrically insulated from the gates 126 in the peripheral region (refer to FIG. 3F(iii)) because the conductive layer 134 is formed on the isolation layer 132 in the peripheral region (refer to FIG. 3F(iii)).

As shown in FIG. 3G, bit lines 134a are formed in the respective reserved bit line regions (refer to 124 of FIG. 3B) by performing an etch-back process on the conductive layer 134. Hard mask layer 136 is formed over the respective bit lines 134a. Here, the conductive layer 134 on the top surface of the isolation layer 132 in the peripheral region (refer to FIG. 3G(iii)) is removed by an etch-back process.

In this embodiment, portions of the isolation layer 132 disposed over the gates 126 are left intact. By leaving isolation layer 132 intact over the peripheral region, conductive layer 134 is not formed in valleys between gates 126 and is more easily removed by the subsequent etch process.

As described above, the gates formed in the peripheral region are patterned in the same process of patterning the bit lines of the cell region. Accordingly, patterns that are otherwise difficult to implement can be easily implemented without additional cost and time.

The above embodiments of the present invention are illustrative and not limitative. Various alternatives and equivalents are possible. The invention is not limited by the type of deposition, etching polishing, and patterning steps described herein. Nor is the invention limited to any specific type of semiconductor device. For example, the present invention may be implemented in a dynamic random access memory (DRAM) device or non-volatile memory device. Other additions, subtractions, or modifications are obvious in view of the present disclosure and are intended to fall within the scope of the appended claims.

What is claimed is:

1. A method of forming a semiconductor device, comprising:
forming an interlayer insulating layer over a cell region of a semiconductor substrate;
forming gate structures over a peripheral region of the semiconductor substrate;
forming reserved bit line regions in the cell region by etching the interlayer insulating layer;
forming gates by etching the gate structures in the peripheral region;
forming a capping insulating layer and an isolation layer over the reserved bit line regions and the gates;
removing portions of the isolation layer disposed over the cell region while leaving portions of the isolation layer disposed over the peripheral is region;
performing an etch-back process on the capping insulating layer; and
forming bit lines in the respective reserved bit line regions.

2. The method according to claim 1, further comprising forming gate electrodes buried in the cell region before forming the interlayer insulating layer.

3. The method according to claim 1, wherein a gate has a square bracket shape.

4. The method according to claim 1, wherein a gate structure is a line pattern including a contact hole pattern.

5. The method according to claim 4, wherein forming the reserved bit line regions further comprises:
forming first mask patterns over the interlayer insulating layer of the cell region; and
etching the interlayer insulating layer by using the first mask patterns as an etch mask.

6. The method according to claim 5, wherein forming the gates further comprises:
forming the first mask patterns while simultaneously forming second mask patterns over the gate structures; and
etching the gate structures by using the second mask patterns as an etch mask.

7. The method according to claim 6, wherein the second mask patterns comprise contact hole patterns which are perpendicular to line patterns and overlap the contact hole patterns.

8. The method according to claim 7, wherein the line and space patterns of the second mask pattern comprise a plurality of first lines interposed with a first line width and a plurality of second lines with a second line width greater than the first line width, in an alternating arrangement.

9. The method according to claim 7, wherein the etching the gate structures is performed simultaneously with the etching the interlayer insulating layer.

10. The method according to claim 1, wherein the gate structure comprises a line and space pattern.

11. The method according to claim 10, wherein forming the reserved bit line regions further comprises:
forming first mask patterns over the interlayer insulating layer of the cell region; and
etching the interlayer insulating layer by using the first mask patterns as an etch mask.

12. The method according to claim 11, wherein forming the gates further comprises:
forming the first mask patterns while simultaneously forming second is mask patterns over the gate structures; and
etching the gate structures by using the second mask patterns as an etch mask.

13. The method according to claim 12, wherein the second mask patterns comprise line and space patterns, a first space pattern overlapped with a central portion of the hole pattern, and a second space pattern spaced apart from the first space pattern.

14. The method according to claim 13, wherein a long-axis direction of the line and space pattern is perpendicular to a long-axis direction of a second pattern.

15. The method according to claim 14, wherein the etching the gate structures is performed simultaneously with the etching the interlayer insulating layer.
